(19) United States
(12) Patent Application Publication
(10) Pub. No.: US 2009/0291549 A1
(43) Pub. Date: Nov. 26, 2009

(54) METAL FILM DECARBONIZING METHOD, FILM FORMING METHOD AND SEMICONDUCTOR DEVICE MANUFACTURING METHOD

(75) Inventors: Hideaki Yamasaki, Yamanashi (JP); Koji Akiyama, Yamanashi (JP); Kazuyoshi Yamazaki, Richardson, TX (US); Yumiko Kawano, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/097,418

(22) PCT Filed: Nov. 24, 2006
(86) PCT No.: PCT/JP2006/323387

§ 371 Date: Jun. 13, 2008

(30) Foreign Application Priority Data
Dec. 16, 2005 (JP) 2005-363680

(51) Int. Cl. H01L 21/26; H01L 21/28

(52) U.S. Cl. 438/585; 438/795; 257/E21.19; 257/E21.328

(57) ABSTRACT

On a Si substrate 1, i.e., a semiconductor substrate, a gate insulating film 2 is formed, and then a W-based film 3a is formed on the gate insulating film 2 by CVD using a film forming gas including W(CO)₆ gas. Then, the film is oxidized under existence of a reducing gas, and the W in the W-based film 3a is not oxidized but only C is selectively oxidized to reduce the concentration of C contained in the W-based film 3a. Then, after performing heat treatment as needed, resist coating, patterning, etching and the like are performed, and, an impurity diffused region 10 is formed by ion implantation and the like, and a semiconductor device having a MOS structure is formed.

### FIELD OF THE INVENTION

The present invention relates to a metal-based film decarbonizing method, a film forming method and a semiconductor device manufacturing method; and, more particularly, to a decarbonizing method for removing carbon stemming from a source material contained in a metal-based film forming a gate electrode or the like in a semiconductor device, e.g., a MOS transistor or the like, a film forming method including a step of performing the decarbonizing method, and a semiconductor device manufacturing method.

### BACKGROUND OF THE INVENTION

Conventionally, a polysilicon (Poly-Si) has been used as a material of the gate electrode of the MOS transistor. As for a method for controlling a threshold voltage of the MOS transistor, there is generally employed a method for doping impurities into a channel region (referred to as a channel doping method) or a method for doping impurities into a Poly-Si film. However, the channel doping method has a drawback in that as a semiconductor device becomes miniaturized, a carrier is affected by an increase in concentration of impurities in the channel region. Further, the Poly-Si doping method has a drawback in that a depletion layer formed at an interface between a Poly-Si film and an underlying gate oxide film deteriorates electrical characteristics in an operation of a gate electrode or resists thinning of the gate oxide film. Moreover, a demand for high integration and high speed of an LSI requires a decrease in a resistance of the gate electrode. Since, however, it is difficult to satisfy such a demand by using the Poly-Si doping method, a metal or a metal-based material such as a metal compound or the like is used as a material of the gate electrode.

In addition, a silicon oxide film has been used as a gate insulating film of a transistor. Meanwhile, along with the trend for miniaturization and high integration of semiconductor devices, the gate insulating film becomes thinner and, also, a leak current increases by a quantum tunneling effect. To that end, there has been developed a gate insulating film made of a high-k dielectric material (high-k material). However, the gate insulating film made of a high-k material has drawbacks in that, when it is used with a Poly-Si gate electrode, a failure occurs on an interface therebetween; an operating voltage increases; or a flow of electrons is disturbed by phonon vibration.

Accordingly, there has been developed a gate electrode (metal gate) which has no depletion layer and is made of a low-resistance metal such as tungsten W or the like. As for a method for forming a metal film or a metal compound film (hereinafter, also referred to as “metal-based film”) to thereby manufacture a metal gate, there has been used a chemical vapor deposition (CVD) method capable of sufficiently coping with the miniaturization of the device and having no need to fuse a high-fusion point metal such as tungsten W or the like.

When a W film or a W compound film is formed by the CVD, it is possible to use, e.g., tungsten hexafluoride (WF₆) gas, as a film forming material. However, when F-containing gas is used, a film quality of an underlying gate oxide film is affected by F, thereby deteriorating a gate insulating film. Hence, in Japanese Patent Laid-open Publication No. 2005-217176, there is suggested a method for forming a W compound film by using a source material containing a metal carbonyl compound such as W(CO)₆ or the like which does not contain F.

In a poly metal gate electrode having a metal-based film and polycrystalline silicon, a selective oxidation process for selectively oxidizing the polycrystalline silicon is performed to suppress damages caused by etching or by ion implantation. At this time, in order to selectively oxidize only silicon without oxidizing the metal-based film that is easily oxidized than silicon, there is suggested a method for performing an oxidization process under existence of water vapor and Hydrogen gas which is described in, e.g., Japanese Patent Laid-open Publication Nos. 2002-176051 and H11-31666.

In a gate electrode manufacturing process, a metal-based film such as a W film or the like is formed on the gate electrode and, then, a heat treatment (annealing) is performed at a high temperature of, e.g., about 1000° C., for the purpose of activating impurities implanted into a source/drain electrode. However, if the W film formed by using a source material containing a metal carbonyl compound suggested in Japanese Patent Laid-open Publication No. 2005-217176 is annealed, a work function of the gate electrode deteriorates. It has been found that the deterioration of the work function is caused by carbon contained in the metal carbonyl compound forming the W film. Accordingly, when a metal-based film (a metal film or a metal compound film) is formed by using a carbon-containing compound as a film forming source material, it is necessary to reduce the concentration of carbon in the film.

As described in Japanese Patent Laid-open Publication Nos. 2002-176051 and H11-31666, in a conventional method for forming a gate electrode, a selective oxidation process for selectively oxidizing silicon without oxidizing a metal film or a metal compound film is performed, as an treatment after the film formation, in order to decrease damages of the gate electrode. However, the technical subject of reducing the concentration of carbon in the metal film or the metal compound film is not considered in the conventional method.

### SUMMARY OF THE INVENTION

In view of the above, the present invention provides a film forming method and a decarbonizing method capable of reducing a concentration of carbon contained in a metal-based film so as to prevent deterioration of electrical characteristics of a semiconductor device.

In accordance with a first aspect of the present invention, there is provided a metal-based film decarbonizing method for performing a decarbonizing process on a metal-based film formed on a substrate in an oxidizing atmosphere under existence of a reducing gas inside a processing chamber.

In the first aspect, preferably, the metal-based film is formed by a CVD by using a film forming material containing a metal compound including at least a metal and carbon.

Further, the decarbonizing process may be a thermal oxidation process performed at a processing temperature greater than or equal to about 650° C. and a processing pressure of about 2 to 1.1×10⁵ Pa under existence of H₂ and H₂O or O_{2.} In this case, a partial pressure ratio of H₂O/H₂ or O₂/H₂ is preferably smaller than or equal to about 0.5.

Further, the decarbonizing process may be a radical oxidation process performed at a processing temperature of about 250 to 450° C. and a processing pressure of about 2 to 5000 Pa under existence of O₂ and H₂. In this case, a partial pressure ratio of O₂/H₂ is preferably smaller than or equal to about 0.5. It is also preferable that the plasma is a microwave-excited high-density plasma generated by introducing microwaves into the processing chamber by using a planar antenna having a plurality of slots.

Moreover, the decarbonizing process may be a UV process performed at a processing temperature of about 250 to 600° C. and a processing pressure of about 2 to 150 Pa under existence of O₂ and H₂. In this case, a partial pressure ratio of O₂/H₂ is preferably be smaller than or equal to about 0.1.

Preferably, a metal forming the metal-based film is at least one species selected from the group consisting of W, Ni, Co, Ru, Mo, Re, Ta and Ti.

Further, a metal compound film which contains a metal contained in the metal compound and at least one of Si and N may be formed by a film forming source material containing at least one of a Si-containing material and a N-containing material. In this case, the Si-containing material is preferably silane, disilane or dichlorosilane. Also, the N-containing material is preferably ammonia or mono-methyl-hydrazin.

Preferably, the metal-based film is formed on a semiconductor substrate via a gate insulating film.

In accordance with a second aspect of the present invention, there is provided a film forming method including: forming a metal film on a substrate disposed in a processing chamber by a CVD method by introducing into the processing chamber a film forming source material containing a metal compound containing at least a metal and carbon; and performing a decarbonizing process on the metal-based film in an oxidizing atmosphere under existence of a reducing gas.

In accordance with a third aspect of the present invention, there is provided a semiconductor device manufacturing method including: forming a metal-based film on a gate insulating film formed on a semiconductor substrate by the film forming method of the second aspect; and forming a gate electrode by using the metal-based film.

In accordance with a fourth aspect of the present invention, there is provided a computer readable storage medium storing therein a computer-executable control program, wherein, when executed, the control program controls a processing chamber such that a metal-based film decarbonizing method for performing a decarbonizing process on a metal-based film formed on a substrate in an oxidizing atmosphere and under existence of a reducing gas inside the processing chamber is implemented.

As set forth above, the concentration of carbon contained in the metal-based film formed on the substrate can be reduced by performing the decarbonizing process on the metal-based film in the oxidizing atmosphere under the existence of the reducing gas inside the processing chamber. Due to the decarbonizing process, the deterioration of the work function of the metal-based film is suppressed even though the annealing process performed thereafter. Accordingly, a semiconductor device such as a MOS transistor or the like can be manufactured without deteriorating electrical characteristics thereof.

### BRIEF DESCRIPTION OF THE DRAWINGS

FIG. 1A schematically shows a state where a gate insulating film is formed on a silicon substrate.

FIG. 1B schematically describes a state where a W-based film is formed on the gate insulating film.

FIG. 1C schematically illustrates a state where a decarbonizing process is performed on the W-based film.

FIG. 1D schematically depicts a state where a MOS transistor is formed.

FIG. 2 provides a cross sectional view of an example of a CVD film forming apparatus for forming a W-based film.

FIG. 3 offers a schematic cross sectional view of an example of a plasma processing apparatus applicable to the present invention.

FIG. 4 explains a planar antenna member.

FIG. 5 presents a graph describing a result of measuring concentrations of C and O in the W film.

FIG. 6 represents a graph depicting changes in a work function of the W film.

FIG. 7 offers a graph showing a result of measuring concentrations of C and O in a W film in a comparative example.

FIG. 8 provides a graph describing a result of measuring concentrations of C and O in a W film in a test example.

FIG. 9 is a graph illustrating results of measuring concentrations of C and O in a W film in cases where a thermal oxidation process is performed and when no thermal oxidation process is performed.

FIG. 10 presents a graph depicting results of measuring concentrations of C and O in a W film in cases where a radical oxidation process is performed and when no radical oxidation process is performed.

FIG. 11 represents a graph showing a result of measuring resistivity of a W film.

### DETAILED DESCRIPTION OF THE EMBODIMENT

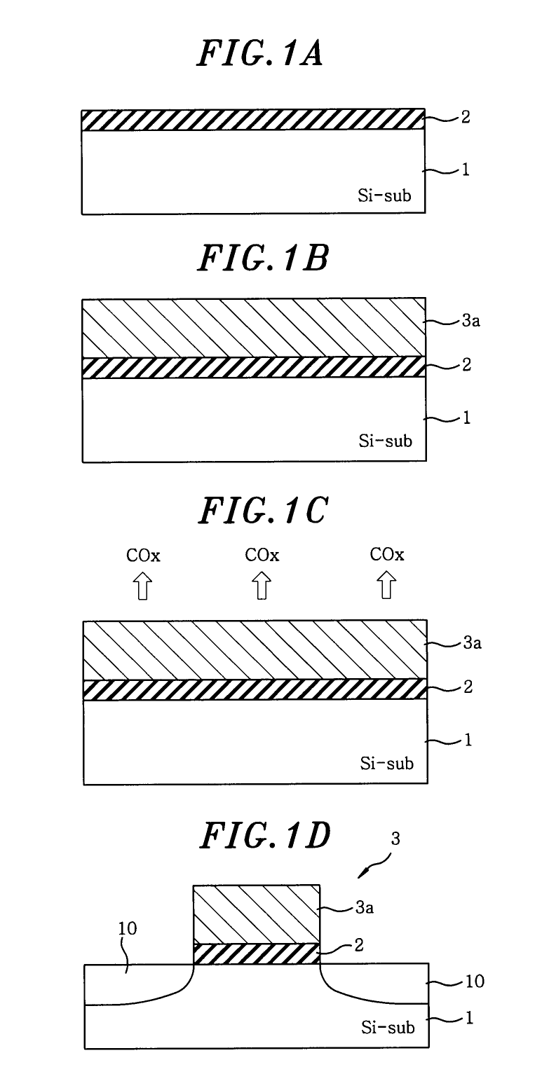

Embodiments of the present invention will be described with reference to the accompanying drawings. FIGS. 1A to 1D are cross sectional views for explaining manufacturing processes of a semiconductor device in accordance with a first embodiment of the present invention. First of all, a gate insulating film 2 is formed on a Si substrate 1 as a semiconductor substrate, as illustrated in FIG. 1A. As for the gate insulating film 2, there can be employed a silicon oxide film (SiO₂), a silicon nitride film (Si₃N₄), a high-k dielectric film (Hi-k film), e.g., an HfSiON film or the like.

Next, as shown in FIG. 1B, a W-based film 3a is formed on the gate insulating film 2 by a CVD using a film forming gas including W(CO)₆ gas as W carbonyl gas. The thicknesses of the gate insulating film 2 and the W-based film 3a can be set to, e.g., about 0.8 to 1.5 nm and about 7 to 50 nm, respectively.

Thereafter, a decarbonizing process is carried out, as can be seen from FIG. 1C. As will be described later, the decarbonizing process is for reducing the concentration of C in the W-based film 3a by selectively oxidizing only carbon C in the W-based film 3a under existence of a reducing gas without oxidizing tungsten W in the W-based film 3a. That is, in the decarbonizing process performed under the existence of the reducing gas, only carbon C is oxidized to CO_{X} (CO, CO₂ or the like) by mild oxidation conditions and carbon C removed from the W-based film 3a.

The decarbonizing process includes, e.g., a thermal oxidation process, a radical oxidation process using a plasma, an UV irradiation process and the like which will be described later. At this time, it is preferable to control a partial pressure ratio between an oxidizing agent and a reducing gas. For example, when O₂ and H₂ gas are used as the oxidizing agent and the reducing gas, respectively, the partial pressure ratio therebetween is appropriately controlled depending on the processing method.

Next, a heat treatment is performed as needed and, then, resist coating, patterning, etching and the like are carried out. Thereafter, an impurity diffused region 10 is formed by ion implantation and the like. Accordingly, there is formed a semiconductor device of a MOS structure (MOS transistor) having a gate electrode 3 formed of the W-based film 3a, as illustrated in FIG. 1D.

As for the W-based film 3a forming the gate electrode 3, there can be employed a W compound film, e.g., a WSi_{X} film, a WN_{X} film or the like, other than the W film. The W compound film is formed by using, e.g., W(CO)₆ gas, Si-containing gas and N-containing gas. By controlling film forming conditions such as flow rates, a temperature of a substrate, a pressure in a processing chamber and the like, the concentrations of Si and N can be arbitrarily changed. Accordingly, a WSi_{X} film, a WN_{X} film and a composite compound film thereof can be formed to have a specific composition ratio. Here, as for the Si-containing gas, it is possible to use, e.g., silane, disilane, dichlorosilane or the like. Further, as for the N-containing gas, it is possible to use, e.g., ammonia, mono-methyl-hydrazin or the like. Moreover, impurity ions such as P, As, B or the like may be implanted into the W-based film 3a. Accordingly, a threshold voltage can be finely controlled.

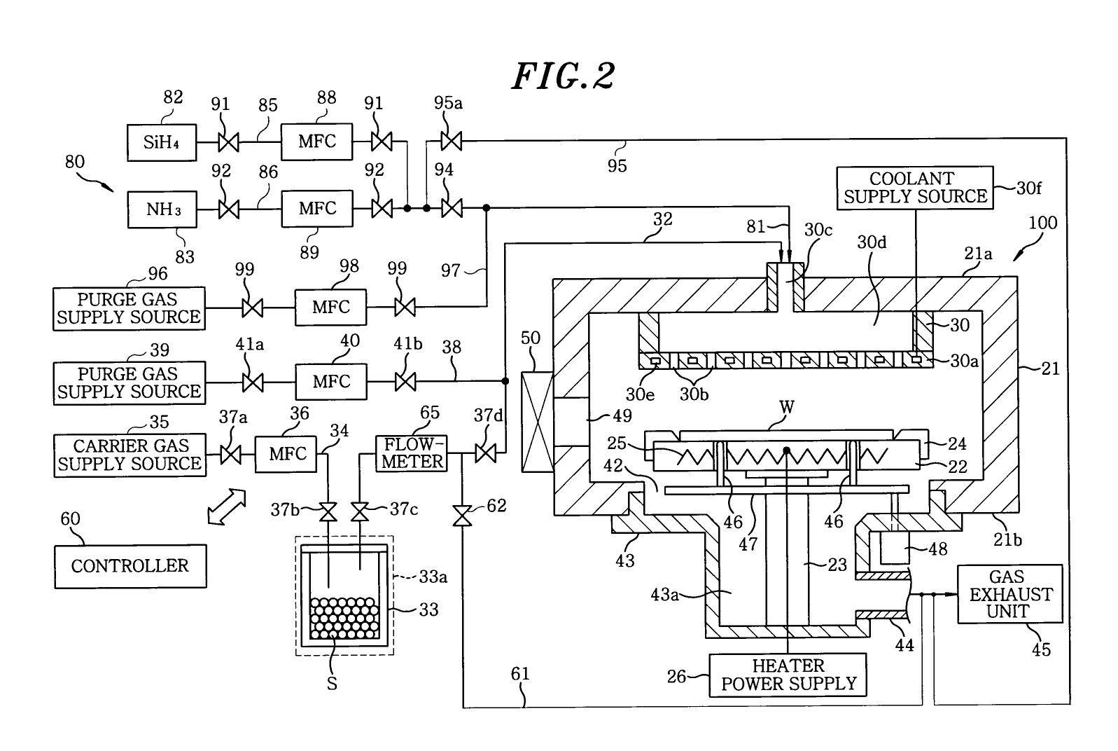

The following is a description of a desired example of the film forming method for forming the W-based film 3a by a CVD using W(CO)₆ gas and at least one of the Si-containing gas and the N-containing gas as needed. FIG. 2 provides a cross sectional view showing an example of a CVD film forming apparatus for forming the W-based film 3a.

The film forming apparatus 100 includes a substantially cylindrical airtight chamber 21. A circular opening 42 is formed at a central portion of a bottom wall 21b of the chamber 21, and a gas exhaust chamber 43 projecting downward is provided to communicate with the opening 42 of the bottom wall 21b. A susceptor 22 made of ceramic, e.g., AlN or the like, is provided in the chamber 21 to horizontally support a wafer W, a semiconductor substrate. Further, the susceptor 22 is supported by a cylindrical supporting member 23 extending upward from a central bottom portion of the gas exhaust chamber 43. A guide ring 24 for guiding the wafer W is provided on an outer edge portion of the susceptor 22. Moreover, a resistance heater 25 is buried in the susceptor 22 to heat the substrate 22 by being supplied with power from a heater power supply 26. The wafer W is heated by heat thus generated. As will be described later, a W(CO)₆ gas introduced into the chamber 21 is thermally decomposed by the heat thus generated. A controller (not shown) is connected to the heater power supply 26, and an output of the heater 25 is controlled in accordance with a signal of a temperature sensor (not shown). Further, a heater (not shown) is buried in a wall of the chamber 21, so that the wall of the chamber 21 can be heated to, e.g., about 40 to 80° C.

The susceptor 22 is provided with three wafer supporting pins (only two are shown) for supporting and vertically moving the wafer W. The wafer supporting pins can be protruded from and retracted into the top surface of the susceptor 22, and are fixed to a supporting plate 47. Further, the wafer supporting pins 46 are raised and lowered through the supporting plate 47 by a driving mechanism 48 such as an air cylinder or the like.

A shower head 30 is provided on a ceiling wall 21a of the chamber 21. Installed under the shower head 30 is a shower plate 30a having a plurality of gas injection openings 30b for injecting a gas toward the susceptor 22. A gas inlet port 30c for introducing a gas into the shower head 30 is installed on an upper wall of the shower head 30, and is connected with a line 32 for supplying W(CO)₆ gas as W carbonyl gas and a line 81 for supplying silane gas as Si-containing gas and ammonia gas as N-containing gas. In addition, a diffusion space 30d is formed inside the shower head 30.

The shower plate 30a is provided with, e.g., a concentrically arranged coolant channel 30e, in order to prevent the decomposition of the W(CO)₆ gas in the shower head 30. By supplying a coolant such as cooling water or the like from a coolant supply source 30f to the coolant channel 30e, a temperature in the shower head 30 can be controlled to about 20 to 100° C.

The other end of the line 32 is inserted into the W source container 33 having therein a solid W(CO)₆ source material S as a metal carbonyl source material. A heater 33a as a heating unit is provided around the W source container 33. A carrier gas line 34 is inserted into the W source container 33. By supplying a carrier gas, e.g., Ar gas, from a carrier gas supply source 35 to the W source container 33 via the line 34, the solid W(CO)₆ source S in the solid form in the W source container 33 is heated and sublimated into W(CO)₆ gas by the heater 33a. The W(CO)₆ gas is supplied by a carrier gas to the diffusion space 30d in the chamber 21 via the line 32.

Moreover, a mass flow controller 36 is installed in the line 34, and valves 37a and 37b are respectively disposed at upstream and downstream sides of the mass flow controller 36. Further, a flowmeter 65 for measuring a flow rate of the W(CO)₆ gas based on, e.g., the amount of the W(CO)₆ gas, is provided in the line 32, and valves 37c and 37d are respectively installed at upstream and downstream sides of the flowmeter 65. A pre-flow line 61 is connected to a downstream side of the flowmeter 65 in the line 32. The pre-flow line 61 is connected to a gas exhaust line 44 to be described later, and the inside of the chamber 21 is exhausted for a specific period of time in order to stably supply the W(CO)₆ gas into the chamber 21. In the pre-flow line 61, a valve 62 is installed at a downstream side of a junction portion with the line 32. Further, a heater (not shown) is disposed around the lines 32, 34 and 61, and is controlled to heat the lines at a temperature where the W(CO)₆ gas is not solidified, e.g., about 20 to 100° C., preferably, about 25 to 60° C.

Moreover, one end of a purge gas line 38 is connected to the line 32. The other end of the purge gas line 38 is connected to a purge gas supply source 39. The purge gas supply source 39 supplies, e.g., a H₂ gas or an inert gas such as Ar gas, He gas, N₂ gas or the like, as a purge gas. By using the purge gas, it is possible to exhaust a film forming gas remaining in the line 32 or perform a purge process in the chamber 21. Further, a mass flow controller 40 is installed in the purge gas line 38, and valves 41a and 41b are disposed at upstream and downstream sides of the mass flow controller 40.

Meanwhile, the other end of the line 81 is connected to a gas supply system 80. The gas supply system 80 includes a SiH₄ gas supply source 82 for supplying SiH₄ gas and a NH₃ gas supply source 83 for supplying NH₃ gas which are connected to gas lines 85 and 86, respectively. The gas line 85 is provided with a mass flow controller 88 and valves 91 disposed at upstream and downstream sides of the mass flow controller 88, and the gas line 86 is provided with a mass flow controller 89 and valves 92 disposed at both sides of the mass flow controller 89. Further, the gas lines are connected to the diffusion space 30d in the chamber 21 via the line 81, and the SiH₄ gas and the NH₃ gas are supplied from the respective gas lines to the gas diffusion space 30d.

Moreover, the line 81 is connected to a pre-flow line 95, and the pre-flow line 95 is connected to the line 44. In order to stably supply the SiH₄ gas and the NH₃ gas to the chamber 21, the gas exhausting process is performed for a predetermined period of time. Furthermore, the pre-flow line 95 is provided with a valve 95a installed at downstream side of a junction portion with the line 81, which will be described later.

Further, one end of a purge gas line 97 is connected to the line 81. The other end of the purge gas line 97 is connected to a purge gas supply source 96. The purge gas supply source 96 supplies H₂ gas or an inert gas such as Ar gas, He gas, N₂ gas, or the like, as a purge gas. By using the purge gas, it is possible to exhaust a film forming gas remaining in the line 81 or perform a purge process in the chamber 21. Further, a mass flow controller 98 is installed in the purge gas line 97, and valves 99 are disposed at upstream and downstream sides of the mass flow controller 98.

The mass flow controllers, the valves and the flowmeter 65 are controlled by a controller 60. Accordingly, the supply and stop of the carrier gas, the W(CO)₆ gas, the SiH₄ gas, the NH₃ gas and the purge gas, and flow rates thereof are controlled to the predetermined flow rates. The flow rate of the W(CO)₆ gas supplied to the gas diffusion space 30d in the chamber 21 is controlled by controlling the flow rate of the carrier gas by the mass flow controller 36 based on the value of the flowmeter 65.

A gas exhaust line 44 is connected to a side of the gas exhaust chamber 43. A gas exhaust unit 45 having a high speed vacuum pump is connected to the gas exhaust line 44. By operating the gas exhaust unit 45, the gas in the chamber 21 is uniformly discharged into the space 43a of the gas exhaust chamber 43 and, hence, the inside of the processing chamber 21 can be depressurized up to a predetermined vacuum level at a high speed.

Provided on a sidewall of the processing chamber 21 are a loading/unloading port 49 for performing loading and unloading of the wafer W between the processing chamber 21 and a transfer chamber (not shown) adjacent to the film forming apparatus 100 and a gate valve 50 for opening and closing the loading/unloading port 49.

In order to form the W-based film 3a by using the film forming apparatus 100, first of all, the gate valve 50 is opened to load the wafer W into the processing chamber 21 through the loading/unloading port 49 and, then, the wafer W is mounted on the susceptor 22. Next, the susceptor 22 is heated by the heater 25, thus heating the wafer W by heat thus generated. Thereafter, the inside of the processing chamber 21 is vacuum exhausted by the vacuum pump of the gas exhaust unit 45 so that a pressure in the chamber 21 is controlled to about 10 to 150 Pa. A heating temperature of the wafer W at that time is preferably about 350 to 650° C.

Next, a carrier gas, e.g., Ar gas, is fed from the carrier gas supply source 35 into the source container 33 having therein a solid W(CO)₆ source material S by opening the valves 37a and 37b. Thereafter, the solid W(CO)₆ source material S is heated and sublimated by the heater 33a. A W(CO)₆ gas is thus produced and then is carried by the carrier gas by opening the valve 37c. Next, preflow is carried out for a predetermined period of time by opening the valve 62. Accordingly, gas exhaust is carried out via a line 61, thus stabilizing a flow rate of the W(CO)₆ gas. Thereafter, the W(CO)₆ gas is introduced into the line 32 and then is supplied to the gas diffusion space 30d in the chamber 21 through the gas inlet port 30c by closing the valve 62 and opening the valve 37d. At this time, it is preferable that the pressure in the chamber 21 is, e.g., about 10 to 150 Pa. The carrier gas is not limited to Ar gas, but it may be another gas, e.g., N₂ gas, H₂ gas, He gas or the like.

In case of forming the W compound film, the W(CO)₆ gas is supplied to the gas diffusion space 30d while at least one of SiH₄ gas and NH₃ gas is supplied to the gas diffusion space 30d. That is, preflow of a gas to be supplied is carried out for a predetermined period of time and, then, gas exhaust is carried out through the line 95, thus stabilizing the flow rate of the corresponding gas. Next, the corresponding gas and the W(CO)₆ gas are supplied to the gas diffusion chamber 30d at the same timing.

When the W(CO) ₆ gas and at least one of SiH₄ gas and NH₃ gas are supplied to the gas diffusion space 30d, a flow rate ratio thereof is controlled to a predetermined level. For example, the flow rates of the W(CO)₆ gas, the SiH₄ gas and the NH₃ gas are controlled to, e.g., about 1 to 20 mL/min (sccm), about 10 to 200 mL/min (sccm) and about 10 to 500 mL/min(sccm), respectively.

The W(CO)₆ gas and at least one of SiH₄ gas and NH₃ gas which are supplied to the gas diffusion space 30d as needed are diffused in the gas diffusion space 30d, and then are uniformly supplied through the gas injection openings 30b of the shower plate 30a toward the surface of the wafer W in the chamber 21. Accordingly, W generated by thermal decomposition of W(CO)₆ reacts with Si of SiH₄ gas and N of NH₃ gas on the surface of the heated wafer W, thereby forming a desired W compound film on the wafer W. When SiH₄ gas and NH₃ gas are used separately, WSiₓ and WN_{X} are formed, respectively. When two or more species of them are used in combination, a composite compound thereof is formed.

When a W compound film of a predetermined film thickness is formed, the supply of the respective gases is stopped. Next, purge gases from the purge gas supply sources 39 and 96 are supplied into the chamber 21, thereby purging the remaining film forming gas. Then, the wafer W is unloaded through the loading/unloading port 49 by opening the gate valve 50.

In the above embodiment, as for a barrier layer and a metal compound film used in a gate electrode, there has been described a case where the W-based film 3a containing W is formed by using W(CO)₆ as metal carbonyl. However, it is also possible to form a metal compound film containing at least one selected from the group consisting of Ni, Co, Ru, Mo, Re, Ta and Ti by using, e.g., at least one selected from the group consisting of Ni(CO)₄, Co₂(CO)₈, Ru₃(CO)₁₂, Mo(CO)₆, Re₂(CO)₁₀, Ta(CO)₆ and Ti(CO)₆, as metal carbonyl. Further, a film forming material forming a metal-based film by a CVD may be a liquid source material or a solid source material other than gas.

Hereinafter, embodiments of the decarbonizing method of the present invention will be described in detail.

### First Embodiment

As for the first embodiment of the decarbonizing method of the present invention, there will be described a thermal oxidation process (selective oxidation) performed in an oxidizing atmosphere using an oxidizing agent under existence of a reducing gas. Here, as for a reducing gas, it is possible to use, e.g., H₂, NH₃ or the like. As for an oxidizing agent, it is possible to use, e.g., O₂, water vapor (H₂O), N₂O, NO or the like.

The thermal oxidation process can be performed in the processing chamber of a diffusion furnace having a known configuration. Desired conditions of the thermal oxidation process will be described hereinafter.

For example, it is preferable that a temperature of a wafer is lower than a conventional annealing temperature (1000° C.), e.g., about 650° C. to 940° C., more preferably, about 700° C. to 900° C. When the wafer temperature is higher than about 940° C., the W-based film 3a forming the gate electrode 3 or the gate insulating film 2 may be oxidized. When the wafer temperature is lower than about 650° C., the decarbonization in the W-based film 3a may be insufficient.

It is preferable that a chamber pressure is, e.g., about 2 to 1.1×10⁵ Pa, more preferably, about 4×x 10⁴ to 1.1×10⁵ Pa. When the processing pressure is greater than 1.1×10⁵ Pa, the W-based film 3a forming the gate electrode 3 or the gate insulating film 2 may be oxidized. When the processing pressure is lower than about 2 Pa, the decarbonization in the W-based film 3a may be insufficient.

As for a gas to be introduced, it is possible to use, e.g., H₂O (water vapor), H₂ and N₂. A flow rate of H₂O is set to about 50 to 500 mL/min (sccm), preferably, about 100 to 300 mL/min (sccm). A flow rate of H₂ is set to about 100 to 2000 mL/min (sccm), preferably, about 300 to 900 mL/min(sccm). A flow rate of N₂ is set to about 200 to 2000 mL/min (sccm), preferably, about 500 to 1500 mL/min (sccm).

Moreover, it is preferable that a partial pressure ratio H₂O/H₂ between the oxidizing agent and the reducing gas is set to, e.g., 0.03 to 0.5, more preferably, 0.1 to 0.3, to oxidize only carbon contained in the metal-based film without oxidizing a metal contained in the metal-based film.

Furthermore, it is preferable that the processing time is set to, e.g., about 300 to 3600 seconds, more preferably, about 600 to 1800 seconds.

### Second Embodiment

Another embodiment of the decarbonizing method is a radical oxidation process using a plasma. The radical oxidation process can be performed in an oxidizing atmosphere using an oxidizing agent under existence of a reducing gas. The reducing gas and the oxidizing agent used in the first embodiment can be used in the second embodiment.

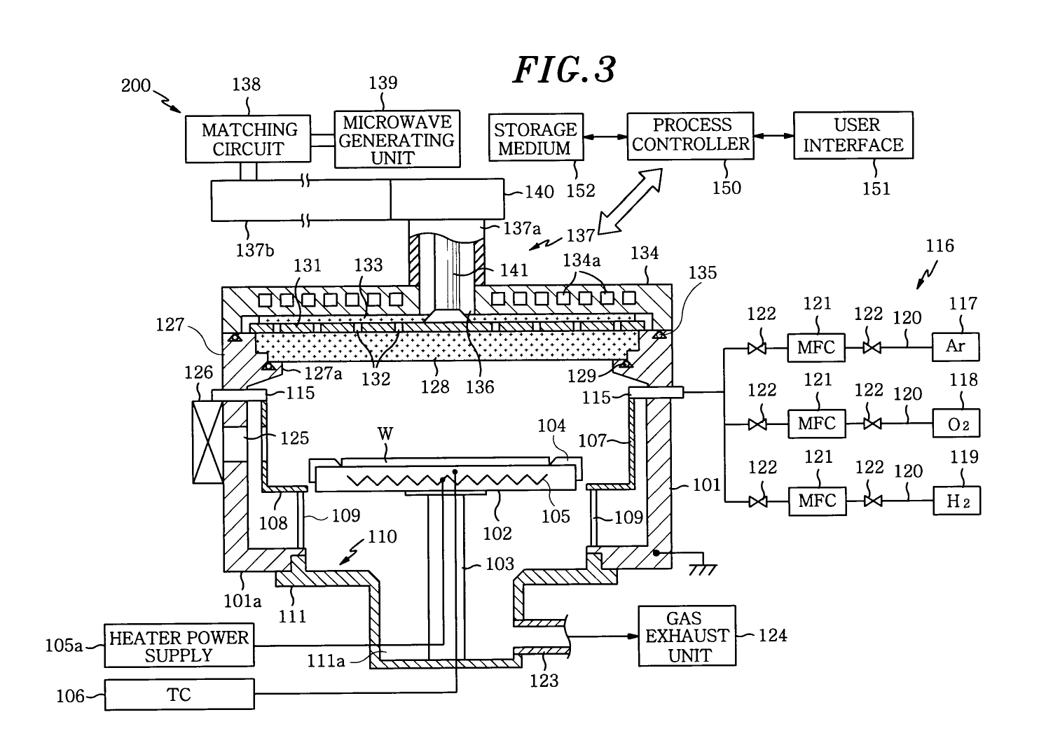

FIG. 3 offers a schematic cross sectional view of an example of a plasma processing apparatus applicable to the radical oxidation process as an example of the decarbonizing method. This plasma processing apparatus 200 is configured as a RLSA (radial line slot antenna) microwave plasma processing apparatus capable of generating a microwave-excited plasma of a high density and a low electron temperature by introducing microwaves into a processing chamber by using a planar antenna having a plurality of slots, particularly an RLSA. Therefore, this plasma processing apparatus 200 can perform a process using a plasma having a density of about 10¹¹ to 10¹³/cm³ and a low electron temperature of about 0.7 to 2 eV, and thus can be appropriately used for performing a decarbonizing process of the present invention in a manufacturing process of various semiconductor devices.

The plasma processing apparatus 200 includes a substantially cylindrical airtight chamber 101 that is grounded. A circular opening 110 is formed at a substantially central portion of a bottom wall 101a of the chamber 101, and a gas exhaust chamber 111 projecting downward is provided on the bottom wall 101a to communicate with the opening 110. The gas exhaust chamber 111 is connected to a gas exhaust unit 124 via a gas exhaust line 123.

A mounting table 102 made of ceramic, e.g., AlN or the like, is provided in the chamber 101 to horizontally support a wafer W, a substrate to be processed. Further, the mounting table 102 is supported by a supporting member 103 extending upward from a central bottom portion of the gas exhaust chamber 111, the supporting member 103 being made of ceramic, e.g., AlN or the like. A cover ring 104 for covering an outer periphery portion of the mounting table 102 and guiding the wafer W is provided on an outer edge portion of the mounting table 102. The cover ring 104 is made of, e.g., quartz, AlN, Al₂O₃, SiN or the like.

A resistance heater 105 is buried in the mounting table 102 to heat the mounting table 102 by being supplied with power from a heater power supply 105a. The wafer W as a substrate to be processed is heated by heat thus generated. Moreover, a thermocouple 106 is arranged in the mounting table 102, so that a heating temperature of the wafer W can be controlled between the room temperature and about 900° C. The mounting table 102 is provided with wafer supporting pins (not shown) for supporting and moving the wafer W up and down. The wafer supporting pins can be protruded from or retracted into the top surface of the mounting table 102.

A cylindrical liner 107 made of quartz is provided on an inner periphery of the chamber 101 in order to prevent metal contamination caused by constituent materials of the chamber. In addition, an annular baffle plate 108 having a plurality of through holes (not shown) is provided at an outer periphery side of the mounting table 102 to uniformly exhaust the inside of the chamber 101. The baffle plate 108 is supported by a plurality of support columns 109.

An annular gas introducing member 115 is provided on a sidewall of the chamber 101, and a gas supply system 116 is connected thereto. The gas introducing member 115 may be disposed in a form of a nozzle shape or a shower shape. The gas supply system 116 includes, e.g., an Ar gas supply source 117, an O₂ gas supply source 118 and an H₂ gas supply source 119, and Ar gas, O₂ gas as an oxidizing agent and H₂ gas as a reducing agent are supplied to the gas introducing member 115 through respective gas lines 120, and then are introduced from the gas introducing member 115 into the chamber 101. Each of the gas lines 120 is provided with a mass flow controller 121 and opening/closing valves 122 disposed at upstream and downstream sides of the mass flow controller 121. Instead of the Ar gas, a rare gas such as Kr, Xe, He or the like can be used.

The gas exhaust line 123 is connected to a side of the gas exhaust chamber 111, and the gas exhaust unit 124 including a high speed vacuum pump is connected with the gas exhaust line 123. By operating the gas exhaust unit 124, a gas in the chamber 101 is uniformly discharged into a space 111a of the gas exhaust chamber 111 via the baffle plate 108 and then is exhausted through the gas exhaust line 123. Accordingly, the inside of the chamber 101 can be depressurized up to a predetermined vacuum level, e.g., 0.133 Pa, at a high speed.

Provided on the sidewall of the chamber 101 are a loading/unloading port 125 for transferring the wafer W between the chamber 101 and a transfer chamber (not shown) adjacent to the plasma processing apparatus 200 and a gate valve 126 for opening and closing the loading/unloading port 125.

An upper portion of the chamber 101 has an opening, and an annular upper plate 127 is connected with the opening. A lower portion of an inner periphery of the upper plate 127 is projected toward an inner space of the chamber to form an annular support portion 127a. A microwave transmitting plate 128 made of a dielectric material, e.g., quartz or ceramic such as Al₂O₃, AlN, or the like, is airtightly disposed on the support portion 127a via a sealing member 129. Therefore, the inside of the chamber 101 is airtightly maintained.

A planar antenna member 131 in a shape of circular plate is provided on the microwave transmitting plate 128 while facing the mounting table 102. The planar antenna member 131 may be formed in, e.g., a shape of a square plate, without being limited to the shape of circular plate, and is fixed to a top portion of the sidewall of the chamber 101. The planar antenna member 131 is made of, e.g., an aluminum plate or a copper plate coated with gold or silver, and has a plurality of slot-shaped microwave radiation holes 132 formed therethrough in a specific pattern.

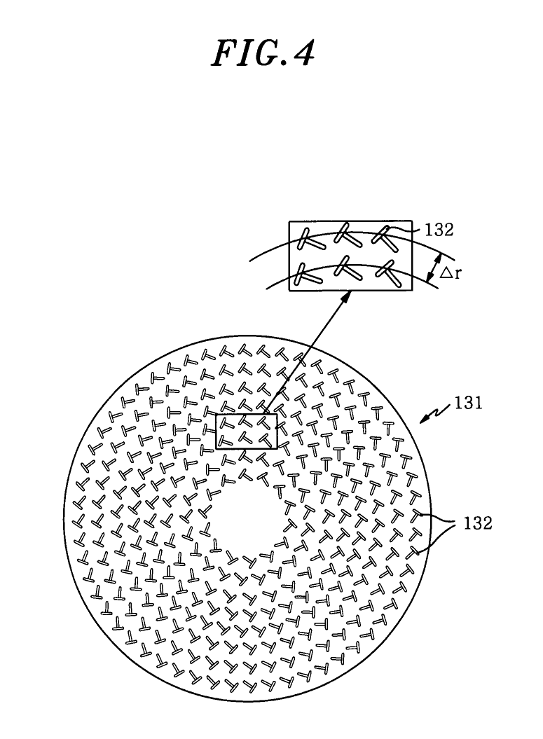

For example, the microwave radiation holes 132 have an elongated shape, as shown in FIG. 4, and typically, the adjacent microwave radiation holes 132 are disposed in a T shape. The plurality of microwave radiation holes 132 is concentrically disposed. A length of the microwave radiation holes 132 and an arrangement interval therebetween are determined depending on a wavelength λg of the microwave. For example, the microwave radiation holes 132 are spaced apart from each other at the interval of λg/2 or λg. Further, in FIG. 4, the interval between the adjacent microwave radiation holes 132 that are concentrically disposed is indicated as Δr. Further, the microwave radiation holes 132 may have another shape, e.g., a circular shape, an arc shape or the like. Further, the microwave radiation holes 132 can be arranged in another pattern, e.g., a spiral pattern, a radial pattern or the like, without being limited to the concentric circular pattern.

Provided on a top surface of the planar antenna member 131 is a retardation member 133 having a dielectric constant greater than that of a vacuum. Since the wavelength of the microwave becomes longer in the vacuum, the retardation member 133 has a function of controlling a plasma by shortening the wavelength of the microwave. The planar antenna member 131 and the microwave transmitting plate 128, and the planar antenna member 131 and the retardation member 133 may be in contact with or separated from each other, and it is preferable that they are in contact with each other.

A shield lid 134 made of a metal material, e.g., aluminum, stainless steel or the like, is provided on a top surface of the chamber 101 to cover the planar antenna member 131 and the retardation member 133. The top surface of the chamber 101 and the shield lid 134 are sealed by sealing members 135. Cooling water paths 134a are formed in the shield lid 134, so that the shield lid 134, the retardation member 133, the planar antenna member 131 and the microwave transmitting plate 128 can be cooled by circulating cooling water through the cooling water paths 134a. Further, the shield lid 134 is grounded.

The shield lid 134 has an opening 136 at a center of a top wall thereof, and a waveguide 137 is connected with the opening 136. A microwave generating unit 139 for generating microwaves is connected with an end portion of the waveguide 137 via a matching circuit 138. Accordingly, a microwave having a frequency of, e.g., 2.45 GHz, which is generated by the microwave generating unit 139, is propagated to the planar antenna member 131 via the waveguide 137. The microwave may have a frequency of 8.35 GHz, 1.98 GHz or the like.

The waveguide 137 includes a coaxial waveguide 137a having a circular cross section and extending upward from the opening 136 of the shield lid 134, and a rectangular waveguide 137b extending in a horizontal direction and connected with an upper portion of the coaxial waveguide 137a via a mode transducer 140. The mode transducer 140 between the rectangular waveguide 137b and the coaxial waveguide 137a has a function of converting a TE mode of the microwave propagating in the rectangular waveguide 137b into a TEM mode. An internal conductor 141 is extended in the coaxial waveguide 137a, and a lower portion of the internal conductor 141 is fixedly connected to a center of the planar antenna member 131. As a consequence, the microwave is efficiently and uniformly propagated to the planar antenna member 131 via the internal conductor 141 of the coaxial waveguide 137a radially.

Each component of the plasma processing apparatus 200 is connected with a process controller 150 having a CPU. The process controller 150 is connected with a user interface 151 having a keyboard, a display and the like. A process operator uses the keyboard when inputting commands for managing the plasma processing apparatus 200, and the display is used to display the operation status of the plasma processing apparatus 200.

Further, the process controller 150 is connected with a storage unit 152 for storing therein control programs (software) for implementing various processes in the plasma processing apparatus 200 under the control of the process controller 150, recipes including processing condition data and the like.

If necessary, the process controller 150 executes a recipe read from the storage unit 152 in response to instructions from the user interface 151, thereby implementing a required process in the plasma processing apparatus 200, e.g., a process for decarbonizing a metal-based film, under the control of the process controller 150.

Further, the control programs or the recipes such as the processing condition data and the like can be stored in a computer-readable storage medium, e.g., a CD-ROM, a hard disk, a flexible disk, a flash memory or the like, or transmitted on-line from another device via, e.g., a dedicated line when necessary.

The plasma processing apparatus 200 of RLSA type configured as described above can perform a decarbonizing process by selectively oxidizing carbon in a tungsten film of the wafer W. In the following, a process sequence thereof will be described.

First of all, the wafer W having on its surface the W-based film 3a is loaded through the loading/unloading port 125 into the chamber 101 by opening the gate valve 126 and then mounted on the mounting table 102. Next, Ar gas, O₂ gas and H₂ gas are respectively introduced at specific flow rates from the Ar gas supply source 117, O₂ gas supply source 118 and H₂ gas supply source 119 into the chamber 101 through the gas introducing member 115.

Desired conditions of the plasma processing will be described hereinafter. For example, a flow rate of O₂ gas can be set to about 50 to 200 mL/min (sccm), preferably, about 70 to 120 mL/min (sccm). A flow rate of H₂ gas can be set to about 100 to 1000 mL/min (sccm), preferably, about 150 to 300 mL/min (sccm). A flow rate of Ar gas can be set to about 500 to 2000 mL/min (sccm), preferably, about 700 to 1500 mL/min (sccm).

Further, it is preferable that a partial pressure ratio O₂/H₂ between the oxidizing agent and the reducing gas is set to, e.g., 0.03 to 0.5, more preferably, 0.1 to 0.2, to oxidize only carbon contained in the film without oxidizing a metal contained in the metal-based film.

Furthermore, it is preferable that the pressure in the chamber is set to, e.g., about 2 to 5000 Pa, more preferably, about 3 to 50 Pa. When the processing pressure is greater than 5000 Pa, the W-based film 3a forming the gate electrode 3 or the gate insulating film 2 may be oxidized. When the processing pressure is lower than about 2 Pa, the decarbonization in the W-based film 3a may be insufficient.

The temperature of the wafer W is preferably set to, e.g., about 250 to 450° C., more preferably, about 350 to 450° C. When the temperature of the wafer W is higher than about 450° C., the W-based film 3a forming the gate electrode 3 or the gate insulating film 2 may be oxidized. When the wafer temperature is lower than about 250° C., the decarbonization in the W-based film 3a is insufficient.

Next, the microwave from the microwave generating unit 139 is transmitted to the waveguide 137 via the matching unit 138. The microwave is supplied to the planar antenna member 131 via the rectangular waveguide 137b, the mode transducer 140 and the coaxial waveguide 137a sequentially, and is then radiated to a space above the wafer W in the chamber 101 through the microwave transmitting plate 128 of the planar antenna member 131. The microwave is propagated in the TE mode in the rectangular waveguide 137b. The TE mode of the microwave is converted into the TEM mode in the mode transducer 140, and the microwave in the TEM mode is propagated through the coaxial waveguide 137a toward the planar antenna member 131. At this time, it is preferable that the power of the microwave is, e.g., about 500 to 5000 W, more preferably, about 2000 to 4000 W. When the microwave power is greater than 5000 W, the W-based film 3a forming the gate electrode 3 or the gate insulating film 2 may be oxidized. When the microwave power is smaller than 500 W, the decarbonization in the W-based film 3a may be insufficient.

An electromagnetic field is formed in the chamber 101 by the microwave radiated from the planar antenna member 131 into the chamber 101 via the microwave transmitting plate 128, thereby converting O₂ gas and H₂ gas into a plasma. By radiating the microwave through the plurality of microwave radiation holes 132 of the planar antenna member 131, the plasma containing oxygen becomes to have a high density ranging from about 10¹¹/cm³ to 10¹³/cm³ and a low electron temperature of about 2 eV or less around the wafer W. The plasma thus generated contains a small number of ions and hence the ions cause less damage to the plasma. Further, only carbon in the W-based film 3a is oxidized by active species in the plasma, mainly by O radicals without oxidizing tungsten in the W-based film 3a. Consequently, only carbon is oxidized to Coₓ to be removed from the W-based film 3a.

### Third Embodiment

As for a third embodiment of the decarbonizing method of the present invention, there will be described a UV irradiation in an oxidizing atmosphere under existence of a reducing gas. The reducing gas and the oxidizing agent used in the first embodiment can be used in the third embodiment.

The UV irradiation can be performed in a processing chamber of a known UV irradiation apparatus having an UV lamp.

Hereinafter, desired conditions of the UV irradiation will be described. For example, it is preferable that the temperature of the wafer W is set to, e.g., about 250 to 600° C., more preferably, about 400 to 480° C. When the temperature of the wafer W is higher than about 600° C., the W-based film 3a forming the gate electrode 3 or the gate insulating film 2 may be oxidized. When the wafer temperature is lower than about 250° C., the decarbonization in the W-based film 3a may be insufficient.

Moreover, it is preferable that a pressure in a chamber (UV processing pressure) is set to, e.g., about 2 to 150 Pa, more preferably, about 5 to 20 Pa. When the pressure in the chamber is greater than 150 Pa, the W-based film 3a forming the gate electrode 3 or the gate insulating film 2 may be oxidized. When the pressure in the chamber is lower than about 2 Pa, the decarbonization in the W-based film 3a may be insufficient.

As for a gas to be introduced, it is possible to use, e.g., O₂, H₂ and Ar. A flow rate of O₂ is set to about 10 to 100 mL/min (sccm), preferably, about 10 to 50 mL/min (sccm). A flow rate of H₂ is set to about 100 to 1000 mL/min (sccm), preferably, about 100 to 500 mL/min (sccm). A flow rate of Ar is set to about 400 to 1200 mL/min (sccm), preferably, about 450 to 800 mL/min (sccm).

At this time, it is preferable that a partial pressure ratio O₂/H₂ between the oxidizing agent and the reducing gas is set to, e.g., 0.01 to 0.1, more preferably, 0.02 to 0.05, in order to oxidize only carbon C contained in the metal-based film without oxidizing a metal contained in the metal-based film.

It is preferable that the amount of UV irradiation by the UV lamp is set to, e.g., about 0.5 to 10 mW/m², more preferably, about 1 to 5 mW/M². When the amount of UV irradiation is greater than 10 mW/M², the W-based film 3a forming the gate electrode 3 or the gate insulating film 2 may be oxidized. When the amount of UV irradiation is smaller than 0.5 mW/m², the decarbonization in the W-based film 3a may be insufficient.

It is preferable that the processing time is, e.g., about 60 to 600 seconds, more preferably, about 100 to 400 seconds.

Hereinafter, a test result which forms the foundation of the present invention will be explained.

### COMPARATIVE EXAMPLE 1

In the film forming apparatus 100 having the configuration same as that illustrated in FIG. 2, a wafer W having a diameter of 300 mm was mounted on the susceptor 22 heated to a predetermined temperature of about 672° C. by a transfer robot. Further, a silicon oxide film (SiO₂ film) was formed in advance on the surface of the wafer W.

Next, a solid W(CO)₆ source material of a solid state contained in a temperature-controlled container was supplied to the film forming apparatus 100 by a bubbling method using Ar gas as a carrier gas, thereby forming a W film having a film thickness of 20 mm on each of sample wafers a, b and c. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

The wafer a is one that a film is deposited thereon (referred to as “as depo”); the wafer b is one that a FGA (forming gas anneal) treatment is performed thereon at 400° C. for 30 minutes under a normal pressure atmosphere of 5% of H₂ (and the remainder N₂) after a film formation is completed; and the wafer c is one that a FGA treatment is performed thereon after a film formation is completed, and, then, an annealing process is performed thereon at 1000° C. for 5 seconds under a normal pressure atmosphere of N₂. Thereafter, the concentrations of C and O in the W film in each of the wafers a to c were measured by an SIMS (secondary ion quadrupole mass spectrometry).

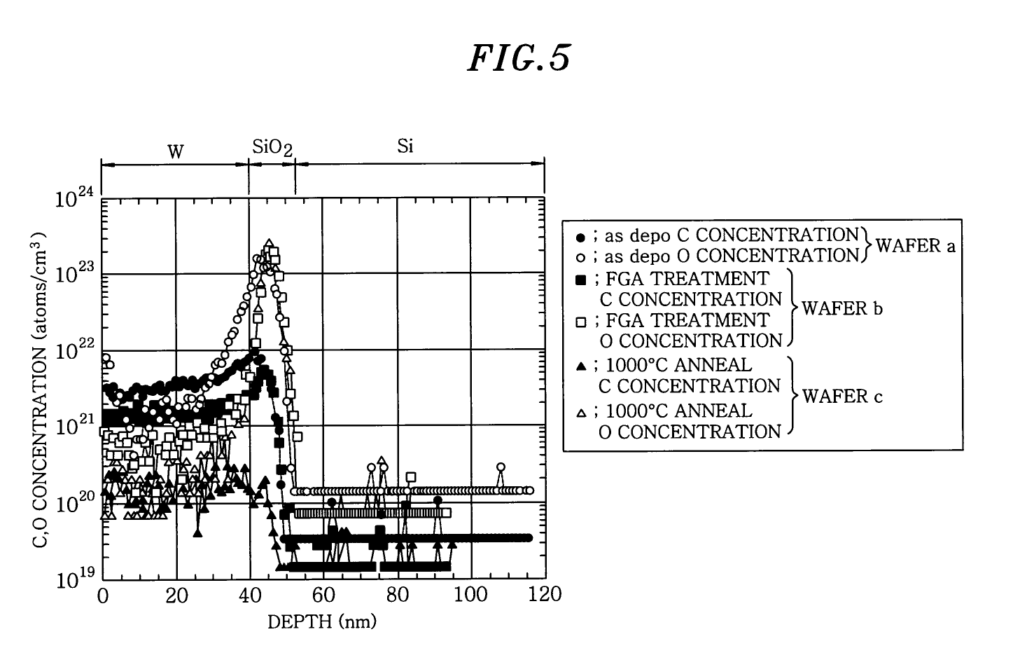

As described in FIG. 5, the C concentration in the W film was about 3×10²¹ atoms/cm³ in the wafer a, about 1.5×10²¹ atoms/cm3 in the wafer b and about 1.5×10²⁰ atoms/cm³ in the wafer c.

According to monitoring of a C concentration profile in a W/SiO₂ interface, In the C concentration profiles of the wafer a (as depo) and the wafer b (after the FGA treatment at 400° C.), points where the profiles in the interface sharply decreased from the W side to the SiO₂ side are coincident with one another. Meanwhile, a point where the profile of the wafer c (after the annealing at 1000° C.) sharply decreased is shifted to the W film surface side.

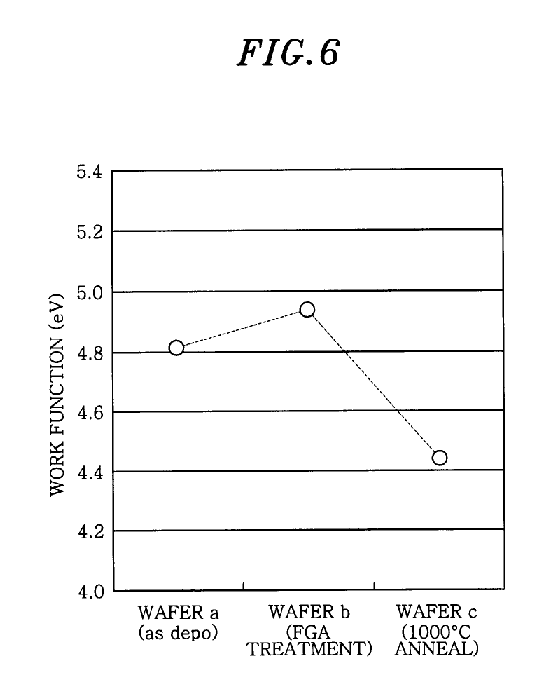

In other words, the C concentration in the W/SiO₂ interface in the wafer c subjected to the annealing at 1000° C. decreased significantly compared to those in the wafers a and b. Further, the work function that was about 4.8 eV to 5 eV in the wafer a (as depo) and the wafer b (after the FGA treatment at 400° C.) decreased to about 4.4 eV in the wafer c (after the annealing at 1000° C.), as depicted in FIG. 6. This is assumed because the annealing at 1000° C. causes diffusion (movement) of C in the W film and from the SiO₂ film and generates defects in the SiO₂ film, thus affecting electrical characteristics thereof.

A work function electrically obtained by creating a MOS capacitor is an apparent work function in which an electronic state of the gate insulating film is applied to an original work function of the metal electrode. It is considered that the deterioration of the work function is caused by the change in the electron state due to the change in the C concentration profile in the W/SiO₂ interface by the annealing at about 1000° C.

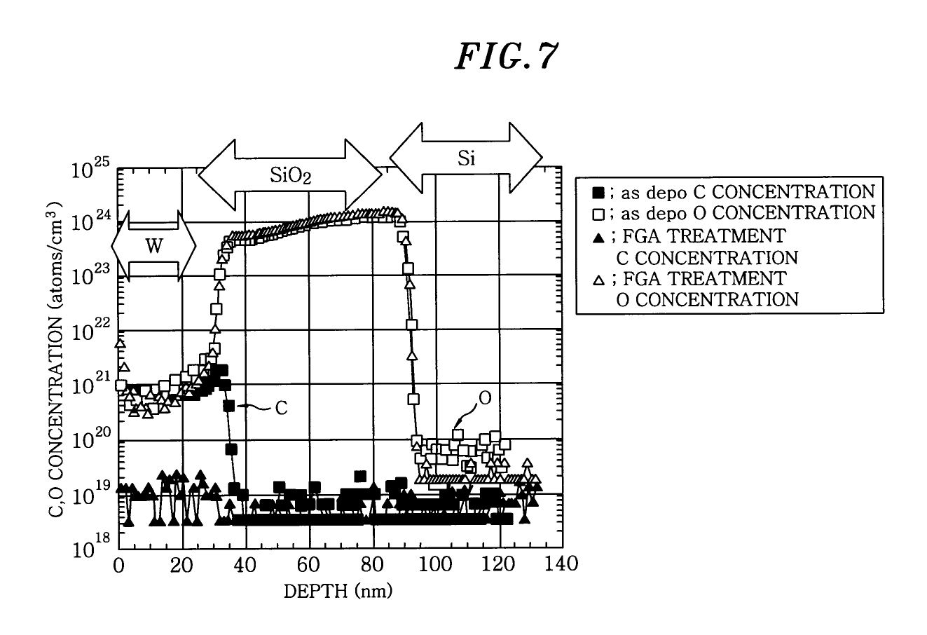

FIG. 7 shows a distribution in a depth direction of concentrations of C and O measured right after the film formation (as depo) and those measured after the annealing at about 1000° C. in the case of forming a W electrode on a thick SiO₂ (SiO₂/Si interface having a depth of about 100 nm). Similar to that shown in FIG. 5, the carbon concentration in the W film decreased after the annealing at about 1000° C. compared to that measured right after the film formation (as depo) and, an inclination of the profile in the tungsten (W)/SiO₂ decreased.

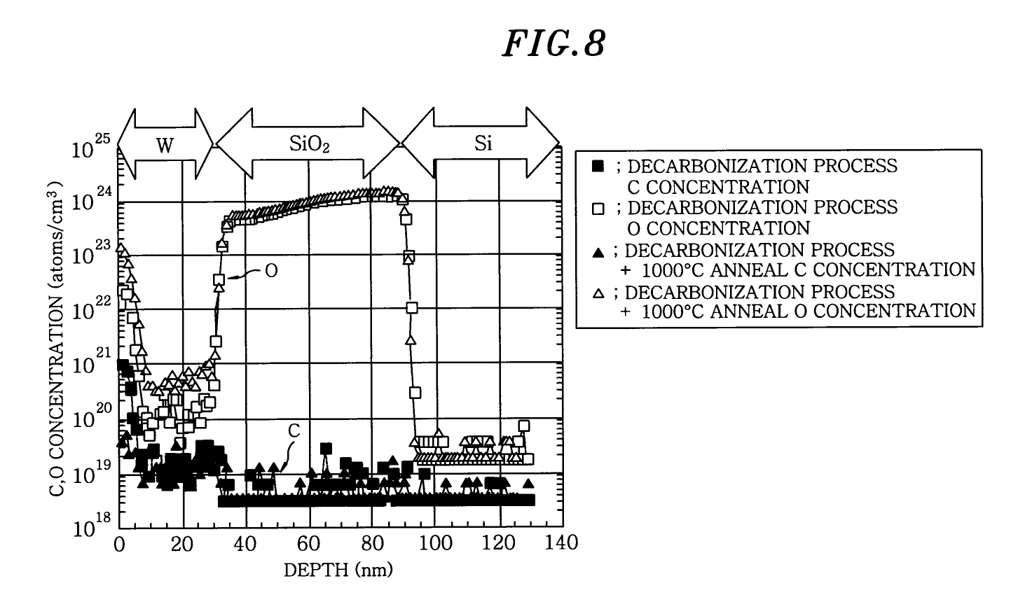

In comparison with the above comparative example, FIG. 8 illustrates profiles of C and O concentrations obtained after performing on the sample of FIG. 7 (SiO₂/Si interface having a depth of about 100 nm) a film forming process and decarbonizing process, i.e., a selective oxidation process in which tungsten is not oxidized but only carbon is oxidized under existence of a reducing gas, and those obtained after performing the decarbonizing process and an annealing process at 1000° C. Further, as for the decarbonizing process, a thermal oxidation (selective oxidation) process was performed on a sample wafer loaded into a diffusion furnace in an atmosphere, where a vapor partial pressure is about 11 kPa, an H₂ partial pressure is about 32 kPa, and the remainder is N₂, at a processing temperature of about 800° C. for a processing time of about 3600 seconds.

As illustrated in FIG. 8, the concentration of C in the W film and the profile in the interface of the W film/SiO₂ film were not changed regardless of the annealing at about 1000° C. This proves that the decarbonizing process can suppress the change of the electron state in the interface even if the annealing at 1000° C. is carried out thereafter.

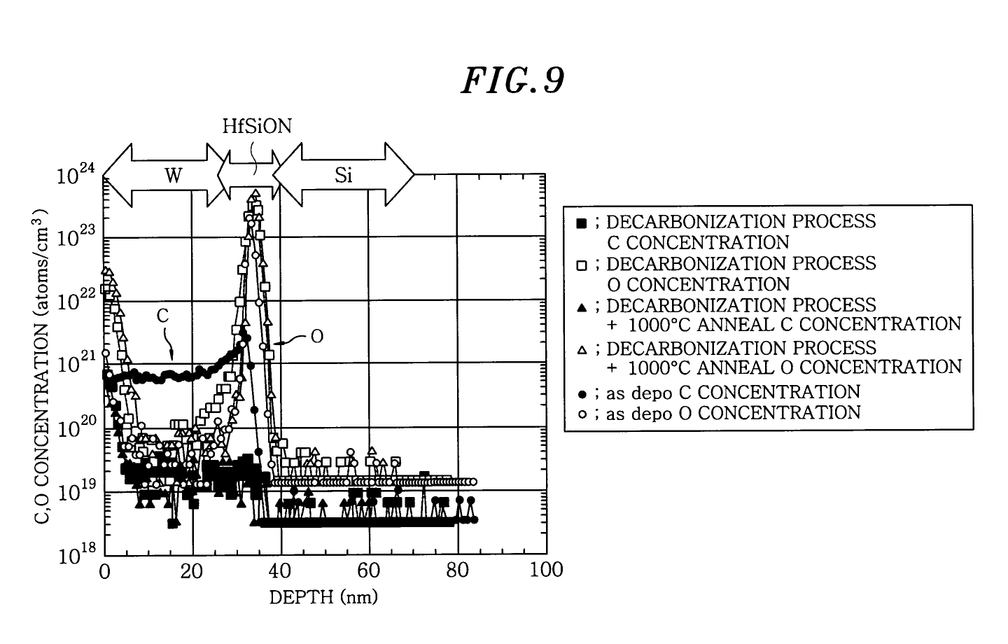

FIG. 9 depicts profiles in a depth direction of C and O concentration obtained right after a W electrode is formed on a Hi-k film (HfSiON film) as a gate insulating film (as depo), those obtained after a decarbonizing process (selective oxidation) using a diffusion furnace and those obtained after the decarbonizing process and an annealing process at 1000° C. The concentration of C in the W film decreased enough by the decarbonizing process, and then was maintained substantially at the same level even after the annealing at 1000° C. was carried out. The profile of the C concentration in the interface between the W film and the HfSiON film which was measured right after the film forming process (as depo) was the same as that obtained after the decarbonizing process (selective oxidation) and that obtained after the decarbonizing process and the annealing process at about 1000° C. In a desired decarbonizing process, the concentration of C in the W film can be decreased while maintaining the C concentration profile in the interface. Since the concentration of C in the W film has been reduced by the decarbonizing process, the profile of the interface can be maintained even after the annealing at about 1000° C. is carried out.

### TEST EXAMPLE 1

In the film forming apparatus 100 having a configuration same as that illustrated in FIG. 2, a wafer W having a diameter of 300 mm was mounted on the susceptor 22 heated to a predetermined temperature of 672° C. by a transfer robot. Next, by using solid W(CO)₆ contained in a temperature controlled container, W(CO)₆ was supplied to the film forming apparatus 100 by a bubbling method using Ar gas as a carrier gas, thereby forming a W film having a film thickness of 20 nm on the wafer W. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

Thereafter, the wafer was loaded into the diffusion furnace for the decarbonizing process and then was subjected to a thermal oxidation (selective oxidation) process performed at about 900° C. for about 300 seconds under an atmosphere, where a partial pressure of water vapor was about 1.2 kPa, a H₂ partial pressure was about 4.0 kPa and the remainder was N₂. As a result of measuring the C concentration in the W film by a SIMS, the C concentration in the W film was about 7.0×10²⁰ atoms/cm³ when the thermal oxidation (selective oxidation) was not performed (as depo). However, the C concentration in the W film was about 2×10¹⁹ atoms/cm³ after the thermal oxidation process.

### TEST EXAMPLE 2

In the film forming apparatus 100 having a configuration same as that illustrated in FIG. 2, a wafer W having a diameter of 300 mm was mounted on the susceptor 22 heated to a predetermined temperature of 672° C. by a transfer robot. Next, by using solid W(CO)₆ contained in a temperature controlled container, W(CO)₆ was supplied to the film forming apparatus 100 by a bubbling method using Ar gas as a carrier gas, thereby forming a W film having a film thickness of 20 nm on the wafer W. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

Then, the wafer was loaded into the diffusion furnace for the decarbonizing process and then was subjected to a thermal oxidation (selective oxidation) process performed at about 850° C. for about 1200 seconds under an atmosphere where a partial pressure of water vapor was about 0.61 kPa, a H₂ partial pressure was about 2.0 kPa and the remainder was N₂. As a result of measuring the C concentration in the W film by a SIMS, the C concentration in the W film was about 7.0×10²⁰ atoms/cm³ when the thermal oxidation (selective oxidation) was not performed (as depo). However, the C concentration in the W film was about 2×10¹⁹ atoms/cm³ after the thermal oxidation process.

### TEST EXAMPLE 3

In the film forming apparatus 100 having a configuration same as that illustrated in FIG. 2, a wafer W having a diameter of 300 mm was mounted on the susceptor 22 heated to a predetermined temperature of 672° C. by a transfer robot. Next, by using solid W(CO)₆ contained in a temperature controlled container, W(CO)₆ was supplied to the film forming apparatus 100 by a bubbling method using Ar gas as a carrier gas, thereby forming a W film having a film thickness of 20 mm on the wafer W. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

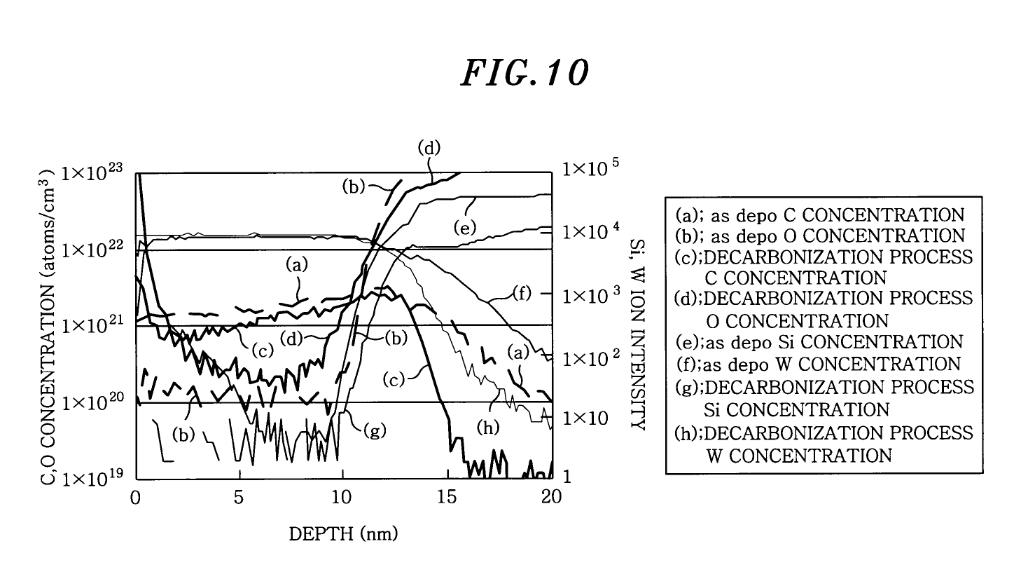

Next, as for the decarbonizing process, a plasma processing was performed by the plasma processing apparatus 200 shown in FIG. 3. At this time, a temperature of the mounting table 102 was about 400° C.; a processing pressure was about 12 Pa; flow rates of O₂ and H₂ as processing gases were about 100 and 200 mL/min (sccm), respectively; a microwave power was about 3.4 kW; and a processing time was about 300 seconds. FIG. 10 provides a result of measuring concentration of C in a W film by a SIMS in the case of performing a plasma processing and in the case of performing no plasma processing (as depo).

Comparing curves between (a) and (c) in FIG. 10, the C concentration in the W film which was measured right after the plasma process was decreased on average from about 1.8×10²¹ atoms/cm³ to about 1.2×10²¹ atoms/cm³ (as dope) and even to about 8×10²⁰ atoms/cm³ (low part).

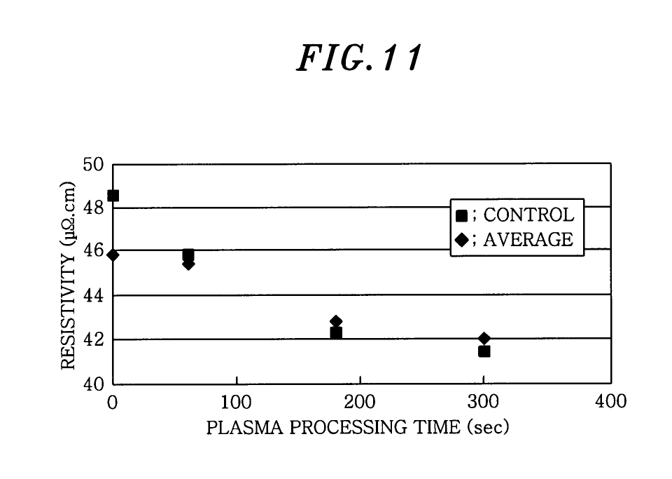

FIG. 11 illustrates a result of measuring resistivity of a W film in the case of changing a processing time of the plasma processing among the aforementioned plasma processing conditions. Referring to FIG. 11, the resistivity decreases as the plasma processing time increases. This is assumed because C in the W film is removed by the plasma process, thus decreasing the resistivity.

### TEST EXAMPLE 4

In the film forming apparatus 100 having a configuration same as that illustrated in FIG. 2, a wafer W having a diameter of 300 mm was mounted on the susceptor 22 heated to a predetermined temperature of 672° C. by a transfer robot. Next, by using solid W(CO)₆ contained in a temperature controlled container, W(CO)₆ was supplied to the film forming apparatus 100 by a bubbling method using Ar gas as a carrier gas, thereby forming a W film having a film thickness of 20 mm on the wafer W. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

Thereafter, as for the decarbonizing process, a plasma processing was performed by the plasma processing apparatus 200 shown in FIG. 3. At this time, a temperature of the mounting table 102 was about 250° C.; a processing pressure was about 12 Pa; flow rates of O₂ and H₂ as processing gases were about 200 mL/min (sccm); a microwave power was about 3.4 kW; and a processing time was about 300 seconds. The C concentration in the W film after the plasma processing was measured by the SIMS.

The C concentration in the W film which was measured after the plasma process was on the average about 1.2×10²¹ atoms/cm³, and was decreased even to about 9×10²⁰ atoms/cm³.

### TEST EXAMPLE 5

In the film forming apparatus 100 having a configuration same as that illustrated in FIG. 2, a wafer W having a diameter of 300 mm was mounted on the susceptor 22 heated to a predetermined temperature of 672° C. by a transfer robot. Next, by using solid W(CO)₆ contained in a temperature controlled container, W(CO)₆ was supplied to the film forming apparatus 100 by a bubbling method using Ar gas as a carrier gas, thereby forming a W film having a film thickness of 20 nm on the wafer W. At this time, a flow rate of a carrier gas (Ar) was about 90 mL/min (sccm); a flow rate of a dilution gas (Ar) was about 700 mL/min (sccm); a pressure in the chamber was about 67 Pa; and a film formation time was about 150 seconds.

Then, a UV irradiation process as a decarbonizing process was performed in a vacuum chamber under following conditions.

Wafer temperature=450° C.

Chamber pressure=7 Pa

Processing gas flow rates=H₂/O₂/Ar=100/10/350 mL/min(sccm)

UV lamp=1.2 mW/m²

Processing time=300 seconds

As a result of measuring the C concentration in the W film after the UV irradiation processing by the SIMS, the C concentration in the W film decreased to about 7×10²⁰ atoms/cm³.

As illustrated in test examples 1 to 5, when the decarbonizing process of the present invention is actually applied to a device, the C concentration in the W film can be reduced before the annealing at about 1000° C. is performed for activation. Therefore, even if the annealing at about 1000° C. is performed later, the C concentration is not changed, so that a potential of a gate insulating film is not varied, thus preventing the deterioration of the work function.

The present invention can be variously modified without being limited to the embodiments of the present invention described above.

For example, in the above embodiments, there has been described the case where a W film formed by using W(CO)₆ as a source material is subjected in a diffusion furnace to a decarbonizing process such as a thermal oxidation process (selective oxidation) in an H₂O/H₂ atmosphere, a radical oxidation process in an O₂/H₂ atmosphere and a UV process in an O₂/H₂ atmosphere. However, the application of this process is not limited to the W film. For example, it can be applied to a WN_{X} film or a WSiₓ film formed by using W(CO)₆ as a W source, or to a metal film or a metal compound film such as a Mo film, a Ru film, a Re film, TaN film, a TaSiN film and the like formed by using as a source material an organic metal compound or a metal carbonyl compound such as Mo(CO)₆, Ru₃(CO)₁₂, Re₂(CO)₁₀, Ta(Nt-Am)(NMe₂)₃ and the like.

In the above embodiments, the RLSA plasma processing apparatus 200 was used as an apparatus for performing the radical oxidation as the decarbonizing process. However, the present invention can be applied to another plasma processing apparatus, e.g., a remote plasma processing apparatus, an ICP plasma processing apparatus, an ECR plasma processing apparatus, a surface reflected wave plasma processing apparatus, a magnetron plasma processing apparatus or the like.

Further, in the above embodiments, there has been described the case where a film forming process is performed on a semiconductor wafer as an object to be processed. However, the object to be processed is not limited thereto, and may also be a glass substrate for a flat panel display (FPD) represented by a liquid crystal display (LCD).

The carbon contained in the metal-based film can be reduced even by appropriately controlling conditions of the conventional heating process and, hence, the effect of decarbonization can be obtained. For example, the effect of decarbonization can be enhanced by performing, after forming the metal-based film, a heating process under existence of an inert gas at a processing temperature of 650 to 850° C. and a processing pressure lower than or equal to about 1 Pa or between 5×10⁴ Pa and 1.1×10⁵ Pa.

What is claimed is:

1. A metal-based film decarbonizing method comprising: performing a decarbonizing process on a metal-based film formed on a substrate in an oxidizing atmosphere under existence of a reducing gas inside a processing chamber.

2. The metal-based film decarbonizing method of claim 1, wherein the metal-based film is formed by a CVD by using a film forming material containing a metal compound including at least a metal and carbon.

3. The metal-based film decarbonizing method of claim 2, wherein the decarbonizing process is a thermal oxidation process performed at a processing temperature greater than or equal to about 650° C. and a processing pressure of about 2 to 1.1×10⁵ Pa under existence of H₂ and H₂O or O₂.

4. The metal-based film decarbonizing method of claim 3, wherein a partial pressure ratio of H₂O/H₂ or O₂/H₂ is smaller than or equal to about 0.5.

5. The metal-based film decarbonizing method of claim 2, wherein the decarbonizing process is a radical oxidation process performed by using a plasma at a processing temperature of about 250 to 450° C. and a processing pressure of about 2 to 5000 Pa under existence of O₂ and H₂.

6. The metal-based film decarbonizing method of claim 5, wherein a partial pressure ratio of O₂/H₂ is smaller than or equal to about 0.5.

7. The metal-based film decarbonizing method of claim 5, wherein the plasma is a microwave-excited high-density plasma generated by introducing microwaves into the processing chamber by using a planar antenna having a plurality of slots.

8. The metal-based film decarbonizing method of claim 2, wherein the decarbonizing process is a UV process performed at a processing temperature of about 250 to 600° C. and a processing pressure of about 2 to 150 Pa under existence of O₂ and H₂.

9. The metal-based film decarbonizing method of claim 8, wherein a partial pressure ratio of O₂/H₂ is smaller than or equal to about 0.1.

10. The metal-based film decarbonizing method of claim 2, wherein the metal-based film includes at least one selected from the group consisting of W, Ni, Co, Ru, Mo, Re, Ta and Ti.

11. The metal-based film decarbonizing method of claim 2, wherein the film forming material further contains at least one of a Si-containing source material and a N-containing source material, and forms a metal compound film including the metal of the metal compound and at least one of Si and N.

12. The metal-based film decarbonizing method of claim 11, wherein the Si-containing source material is silane, disilane or dichlorosilane.

13. The metal-based film decarbonizing method of claim 11, wherein the N-containing source material is ammonia or mono-methyl-hydrazin.

14. The metal-based film decarbonizing method of claim 1, wherein the metal-based film is formed on a semiconductor substrate via a gate insulating film.

15. A film forming method comprising:
forming a metal film on a substrate disposed in a processing chamber by a CVD method by introducing into the processing chamber a film forming material containing a metal compound including at least a metal and carbon; and
performing a decarbonizing process on the metal-based film in an oxidizing atmosphere under existence of a reducing gas.

16. The film forming method of claim 15, wherein the decarbonizing process is a thermal oxidation process performed at a processing temperature greater than or equal to about 650° C. and a processing pressure of about 2 to 1.1×10⁵ Pa under existence of H₂ and H₂O or O₂.

17. The film forming method of claim 16, wherein a partial pressure ratio of H₂O/H₂ or O₂/H₂ is smaller than or equal to about 0.5.

18. The film forming method of claim 15, wherein the decarbonizing process is a radical oxidation process performed by using a plasma at a processing temperature of about 250 to 450° C. and a processing pressure of about 2 to 5000 Pa under existence of O₂ and H₂.

19. The film forming method of claim 18, wherein a partial pressure ratio of O₂/H₂ is smaller than or equal to about 0.5.

20. The film forming method of claim 18, wherein the plasma is a microwave-excited high-density plasma generated by introducing microwaves into the processing chamber by using a planar antenna having a plurality of slots.

21. The film forming method of claim 15, wherein the decarbonizing process is a UV process performed at a processing temperature of about 250 to 600° C. and a processing pressure of about 2 to 150 Pa under existence of O₂ and H₂.

22. The film forming method of claim 21, wherein a partial pressure ratio of O₂/H₂ is smaller than or equal to about 0.1.

23. The film forming method of claim 15, wherein the metal-based film includes at least one selected from the group consisting of W, Ni, Co, Ru, Mo, Re, Ta and Ti.

24. The film forming method of claim 15, wherein the film forming material further contains at least one of a Si-containing source material and a N-containing source material, and forms a metal compound film including the metal of the metal compound and at least one of Si and N.

25. The film forming method of claim 24, wherein the Si-containing source material is silane, disilane or dichlorosilane.

26. The film forming method of claim 24, wherein the N-containing source material is ammonia or mono-methyl-hydrazin.

27. The film forming method of claim 15, wherein the metal-based film is formed on a semiconductor substrate via a gate insulating film.

28. A semiconductor device manufacturing method comprising:
forming a metal-based film on a gate insulating film formed on a semiconductor substrate by the film forming method described in claim 15; and
forming a gate electrode by using the metal-based film.

29. A computer readable storage medium storing therein a computer-executable control program, wherein, when executed, the control program controls a processing chamber to perform a decarbonizing process on a metal-based film formed on a substrate in an oxidizing atmosphere and under existence of a reducing gas inside the processing chamber.
